(19) United States
(12) Patent Application Publication
(10) Pub. No.: US 2007/0004165 A1
(43) Pub. Date: Jan. 4, 2007

(54) Embedded thin layer capacitor, layered structure, and fabrication method of the same

(75) Inventors: Hyo Soon Shin, Yongin (KR); Soon Gil Yoon, Daejeon (KR); Eun Tae Park, Yongin (KR); Soo Hyun Lyoo, Yongin (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/319,820

(22) Filed: Dec. 28, 2005

(30) Foreign Application Priority Data
Jun. 30, 2005 (KR) 10-2005-57907

(51) Int. Cl. H01L 21/20

(52) U.S. Cl. 438/393

(57) ABSTRACT

The present invention relates to a thin layer capacitor including first and second metal electrode layers and a dielectric layer of BiZnNb-based amorphous metal oxide having a dielectric constant of at least 15, interposed between the metal layers, and a layered structure having the same. The layered structure includes a first metal electrode layer formed on a polymer-based composite substrate, a dielectric layer, formed on the first metal electrode layer, and made of BiZnNb-based metal oxide with a dielectric constant of at least 15, and a second metal electrode layer formed on the dielectric layer. The BiZnNb-based amorphous metal oxide in this invention has a high dielectric constant without a thermal treatment for crystallization, useful for fabrication of a thin layer capacitor of a polymer-based layered structure such as a PCB.

### CLAIM OF PRIORITY

This application claims the benefit of Korean Patent Application No. 2005-57907 filed on Jun. 30, 2005, in the Korean Intellectual Property Office, the disclosure of which is incorporated herein by reference.

### BACKGROUND OF THE INVENTION

1. Field of the Invention

The present invention relates to an embedded capacitor, and more particularly, to a dielectric layer having a high dielectric constant even in low-temperature deposition conditions, and an embedded capacitor and a Printed Circuit Board (PCB) having the same.

2. Description of the Related Art

In general, various passive elements mounted on a Printed Circuit Board (PCB) have been perceived as hindrances to miniaturization of electronic devices. Particularly, more and more semiconductor active elements have been embedded types and thus the number of accompanying input/output terminals has been increasing as well. Accordingly, more space is required around the active element, but this has not been a simple problem to address.

The most representative example of passive element is capacitor. A capacitor needs to be disposed properly so that inductance due to increase in frequency is reduced. For example, a decoupling capacitor used for stable supply of power needs to be disposed within a close distance to the input terminal in order to reduce inductance due to high frequency.

In order to meet the needs of miniaturization and high frequency, diverse forms of low Equivalent Series Inductance (ESL) layered capacitors have been developed, but the conventional Multi-Layer Ceramic and aluminum organic Capacitor (MLCC) is a discrete element which has a fundamental limitation in overcoming the above-described problem. Therefore, there have been active studies recently on fabrication of embedded capacitors as an alternative.

Embedded capacitors are embedded in Printed Circuit Boards (PCB) used in memory cards, Personal Computer (PC) main boards and various Radio Frequency (RF) modules, considerably reducing the product size overall. In addition, they can be disposed near the input terminal of an active element, minimizing the length of wires, thereby greatly reducing inductance.

The PCB includes a polymer-based composite having a low dielectric constant, which makes it difficult to form a layer having high level of dielectric constant. There has been a technique in which high-dielectric material powder such as BaTiO₃ is spread on a polymer layer such as FR4 used in the PCB, thereby increasing dielectric constant, but this method faces a limit as to improve the level of dielectric constant only up to a certain level, according to the mixing rule.

Alternatively, a layered structure of a thin capacitor including a dielectric layer having a high dielectric constant and a metal electrode layer can be inserted into the PCB. In this method, as the polymer-based composite substrate is fragile to high temperature, the metal electrode layer and the dielectric layer are formed via low-temperature deposition such as low-temperature sputtering. In general, a dielectric layer formed at a low temperature does not possess crystallinity, having low level of dielectric constant (e.g. up to 5).

Therefore, the dielectric layer requires an additional thermal treatment after deposition to enhance the dielectric constant. However, such thermal treatment is conducted typically at a high temperature of 400° C. or higher, which cannot be applied to PCBs made of polymer-based composite substrate.

Therefore, there has been a need for a new dielectric material having sufficiently high level of dielectric constant even when the dielectric layer is formed at room temperature. Such dielectric technology is the key to a practical use of the thin layer capacitor in a layered structure.

### SUMMARY OF THE INVENTION

The present invention has been made to solve the foregoing problems of the prior art and it is therefore an object of the present invention to provide a thin layer capacitor having a dielectric layer capable of having sufficiently high level of dielectric constant even in low-temperature deposition process, and a fabrication method of the same.

It is another object of the invention to provide a layered structure including a thin layer capacitor having a sufficiently high level of dielectric constant even in low-temperature deposition process, and a fabrication method of the same.

According to an aspect of the invention for realizing the object, there is provided a thin layer capacitor comprising first and second metal electrode layers and a dielectric layer of BiZnNb-based amorphous metal oxide interposed between the metal layers, the dielectric layer having a dielectric constant of at least 15.

Preferably, the BiZnNb-based amorphous metal oxide is expressed as BiₓZn_{y}Nb_{z}O₇, where 1.3<x<2.0, 0.8<y<1.5, and 1.4<z<1.6. Particularly, the dielectric layer has a dielectric constant of at least 30, and further at least 40. Preferably, the dielectric layer has a thickness of 50 nm to 1 μm, and 200 μm to 500 nm.

Preferably, at least one of the first and second metal electrode layers is made of at least one selected from a group consisting of Cu, Ni, Al, Pt, Ta, and Ag.

In addition, there may be an additional buffer layer between at least one of the first and second metal electrode layers and the dielectric layer to enhance adhesion between the at least one metal electrode layer and the dielectric layer. The buffer layer may be made of Ni.

According to another aspect of the invention for realizing the object, there is provided a layered structure comprising: a first metal electrode layer formed on a polymer-based composite substrate; a dielectric layer, formed on the first metal electrode layer, the dielectric layer made of BiZnNb-based metal oxide with a dielectric constant of at least 15; and a second metal electrode layer formed on the dielectric layer.

The polymer-based composite substrate may comprise polyimide or epoxy, and a Printed Circuit Board (PCB) may be the most representative example of the layered structure.

According to further another aspect of the invention for realizing the object, there is provided a fabrication method of a thin layer capacitor comprising steps of: forming a dielectric layer on a first metal electrode layer, the dielectric layer made of a BiZnNb-based metal oxide with a dielectric constant of at least 15; and forming a second electrode layer on the dielectric layer.

Preferably, the step of forming a dielectric layer is conducted using low-temperature deposition at a temperature up to 100° C., and more preferably, at room temperature. Such low-temperature deposition process includes low-temperature sputtering, Pulsed Laser Deposition and Chemical Vapor Deposition.

In a particular embodiment, the fabrication method of a thin layer capacitor may further comprise a step of thermal treatment at a temperature range in which the metal composite is not crystallized, after the step of forming a dielectric layer.

The thermal treatment of the dielectric layer may be conducted at a temperature ranging from 100 to 200° C.

The step of forming a second metal electrode layer may comprise one selected from a group consisting of sputtering conductible at low temperature, evaporation, and electroless plating.

According to further another aspect of the invention for realizing the object, there is provided a fabrication method of a layered structure comprising steps of: forming a first metal electrode layer on a polymer-based composite substrate; forming a dielectric layer on the first metal electrode layer, the dielectric layer made of a BiZnNb-based metal oxide with a dielectric constant of at least 15; and forming a second metal electrode layer on the dielectric layer.

In order to fabricate the layered structure such as a PCB, the fabrication method may further comprise a step of compressing the polymer-based composite substrate on the second metal electrode layer.

The inventor has confirmed that BiZnNb-based metal oxide formed via deposition process such as low-temperature sputtering can have dielectric characteristics (dielectric constant of at least 15) practicable for a capacitor without the thermal treatment for crystallization. Typically, BiZnNb-based metal oxide is known to have pyrochlore phase. However, the BiZnNb-based metal oxide adopted in this invention is used in low-temperature deposited state, without the thermal treatment for forming pyrochlore phase, and can be defined as an amorphous form close to pyrochlore phase.

As such, it was confirmed that the BiZnNi-based amorphous metal oxide exhibits a high dielectric constant of at least 15, preferably at least 30, and most preferably at least 45 without the high-temperature thermal treatment for crystallization. Therefore, a thin layer capacitor can be realized using the BiZnNi-based dielectric layer proposed in the invention in layered structures such as a PCB of polymer-based composite substrate

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a layered structure including an embedded thin layer capacitor according to an embodiment of the present invention;

FIGS. 2a to 2d are sectional views illustrating the fabrication method of a layered structure according to the present invention;

FIG. 3 is a sectional view illustrating the layered structure including the embedded thin layer capacitor according to another embodiment of the present invention;

FIGS. 4a to 4d are graphs showing dielectric constants and high-frequency losses of (Bi, Zn, Ni)-based oxide adopted in the present invention and (Ba, Zn)-based oxide of the conventional dielectric layer; and

FIG. 5 is a graph illustrating the results of XRD analysis of (Bi, Zn, Ni)-based oxide adopted for the dielectric layer in the present invention.

### DETAILED DESCRIPTION OF THE PREFERRED EMBODIMENT

Preferred embodiments of the present invention will now be described in detail with reference to the accompanying drawings.

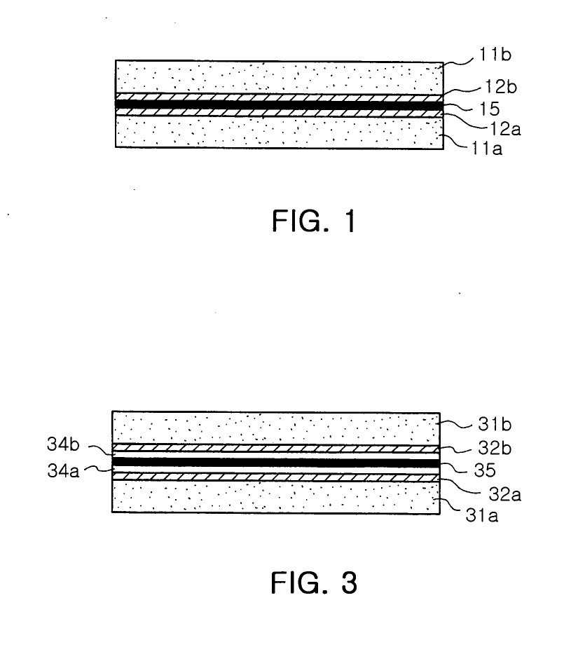

FIG. 1 is a sectional view illustrating a layered structure including an embedded thin layer capacitor according to an embodiment of the present invention.

FIG. 1 illustrates the layered structure including the embedded thin layer capacitor. The layered structure may be a Printed Circuit Board (PCB) including polymer-based composite substrates 11a and 11b. The substrates 11a and 11b may be polyimide or epoxy usually used for a PCB.

The thin layer capacitor according to an embodiment includes first and second metal electrode layers 12a and 12b, and a BiZnNb-based dielectric layer 15 between the two layers. The dielectric layer 15 is made of BiZnNb-based amorphous metal oxide. The amorphous BiZnNb-based metal oxide has a dielectric constant of at least 15, and preferably a dielectric constant of at least 30. Preferably, the dielectric layer 15 adopted in the present invention is metal oxide expressed as BiₓZn_{y}Nb_{z}O₇, where 1.3<x<2.0, 0.8<y<1.5, and 1.4<z<1.6. The dielectric layer 15 can have a thickness of preferably 50 nm to 1 μm, and more preferably, 200 to 500 nm, in order to be used in an embedded capacitor in a PCB.

The dielectric layer 15 may be formed by low-temperature deposition process such as sputtering, Pulsed Laser Deposition (PLD) or Chemical Vapor Deposition (CVD). The dielectric layer 15 can be formed preferably at a temperature of 100° C. or lower, or more preferably at room temperature.

At least one of the first and second metal electrode layers 12a and 12b can be made of at least one selected from a group consisting of Cu, Ni, Al, Pt, Ta, and Ag. The first and second metal electrode layers 12a and 12b may be formed via low-temperature sputtering, evaporation or electroless plating.

The dielectric layer 15 adopted in the present invention has a sufficiently high level of dielectric constant even only via low-temperature deposition process, without a thermal treatment at a high temperature, and therefore, can effectively be adopted in a polymer-based layered structure such as a PCB.

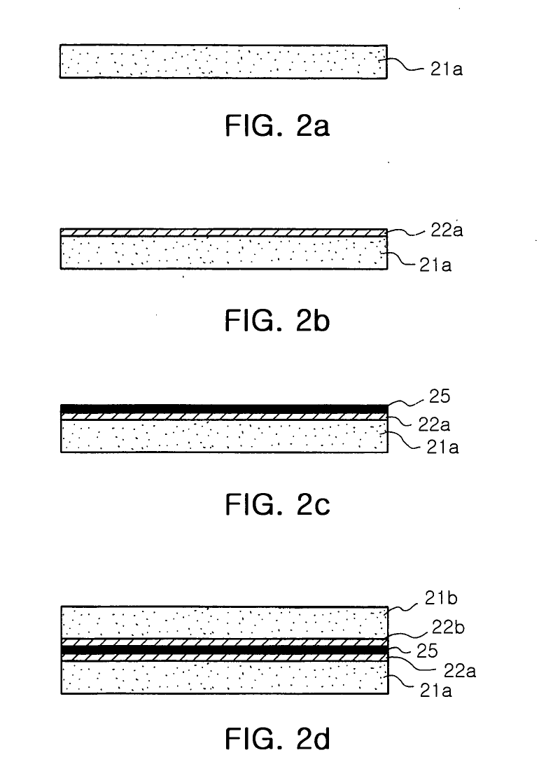

FIGS. 2a to 2d are sectional views illustrating a fabrication method of the embedded thin layer capacitor according to the present invention.

As shown in FIG. 2a, the process starts with a step of preparing a polymer-based composite substrate 21a. The polymer composite constituting the substrate 21a may include polyimide or epoxy.

Then as shown in FIG. 2b, a first metal electrode layer 22a is formed on the polymer substrate 21a. The first metal electrode layer 22a may be at least one selected from a group including Cu, Ni, Al, Pt, Ta, and Ag. The first metal electrode layer 22a is formed on the polymer substrate which is fragile to fire, and thus is formed using low-temperature deposition process. Such process includes low-temperature sputtering, evaporation and electroless plating.

Next, as shown in FIG. 2c, the dielectric layer 25 is formed on the first metal electrode layer 22a. The dielectric layer 25 adopted in this invention is BiZnNb-based amorphous metal oxide. It is preferable that the dielectric layer 25 is formed using low-temperature deposition at a temperature of 100° C. or lower, and further, using low-temperature deposition at room temperature. Such process includes sputtering or Pulsed Laser Deposition (PLD) using BiZnNb metal composite target, or Chemical Vapor Deposition (CVD) using each metal source. The dielectric layer 25 obtained via low-temperature deposition is composed of amorphous metal oxide having sufficiently high level of dielectric constant, and thus the thermal treatment at high temperature for crystallization is not required.

Still, depending on the needs, the dielectric layer 25 may be thermally treated in a temperature range that does not allow crystallization of the dielectric layer 25. As a result, the dielectric layer 25 is not crystallized in a pyrochlore crystal structure, but exhibits a high dielectric constant of at least 45 (refer to Example 3). Such temperature range is much lower than that of a thermal treatment for high-temperature crystallization. Thus, in case of using polymer-based composite substrate as in this embodiment, it is preferable to conduct a thermal treatment in a temperature range that does not bring deformation to the substrate 21a. The preferable temperature range of the thermal treatment adopted in the present invention is 100 to 200° C.

Thereafter, as shown in FIG. 2d, a second electrode layer 22b is formed on the dielectric layer 25. The second metal electrode layer 22b may be formed by similar material and process as the first metal electrode layer 22a. Then, as in a typical manufacturing process of a PCB, an additional polymer-based composite substrate 21b may be compressed on the second metal electrode layer 22b.

As described above, the BiZnNb-based amorphous metal oxide has a high dielectric constant without going through a high-temperature thermal treatment for crystallization, and may be used to form a layered structure containing FR4, polyimide and epoxy. That is, it has a high dielectric constant of at least 15 in an uncrystallized state, and can even have a dielectric constant of at least 30 or at least 45 via adjustment of composition range and via conducting low-temperature thermal treatment. Such high level of dielectric constant is the level required for a high-capacity decoupling capacitor, and therefore, the BiZnNb-based amorphous metal oxide is positively applicable to a new dielectric layer, which is crucial in practical use of the embedded thin layer capacitor and a PCB including the same.

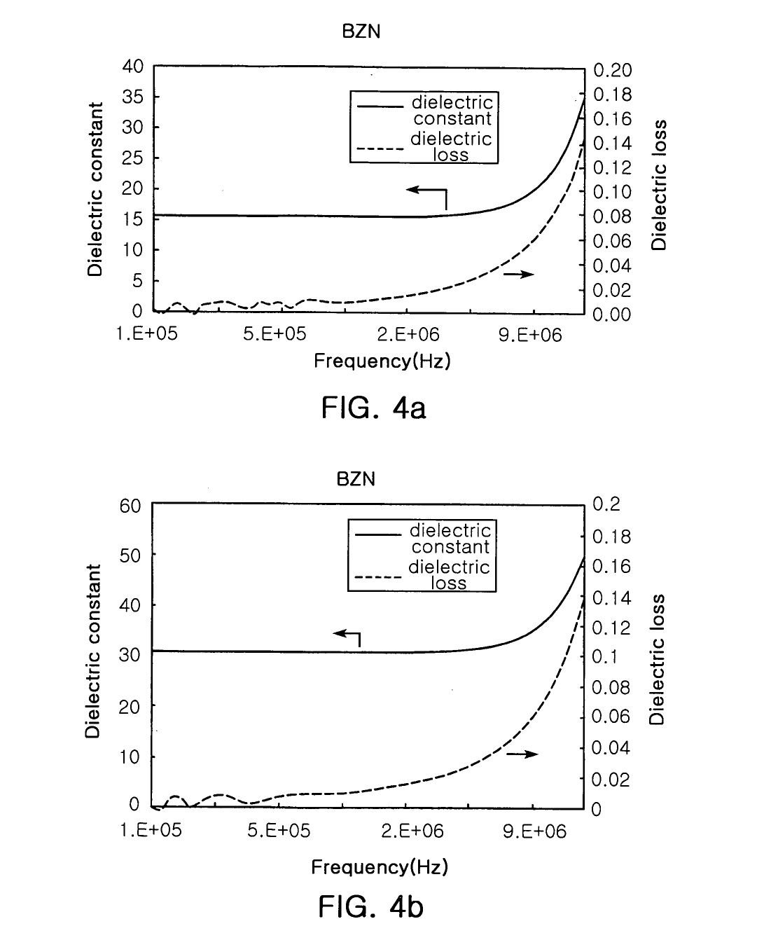

FIG. 3 is a sectional view illustrating an embedded thin layer capacitor according to another embodiment of the present invention.

FIG. 3 illustrates the layered structure including the thin layer capacitor. Similar to the layered structure shown in FIG. 1, the layered structure may be a PCB including the polymer-based composite substrate 31a.

The dielectric layer 35 is BiZnNb-based amorphous metal oxide, having a dielectric constant of at least 15, and preferably, at least 30. It is preferable that when the dielectric layer of the BiZnNb-based metal oxide is expressed as BiₓZn_{y}Nb_{z}O₇, it satisfies 1.3<x<2.0, 0.8<y<1.5, 1.4<z<1.6. The thin layer capacitor according to this embodiment further includes buffer layers 34a and 34b between the first and second metal electrode layers 32a and 32b and the BiZnNb-based dielectric layer 35. The buffer layers 34a and 34b are provided to maintain high adhesion intensity between the first and second metal electrode layers and the BiZnNb-based dielectric layer 35, functioning to relieve the problematic thermal stress. The buffer layers 34a and 34b are advantageous in relieving the thermal stress generated between the adjacent two layers. As long as not acting as part of the capacitor, any metal, preferably Ni, can be used to form the buffer layers. Depending on the material adopted, the buffer layers 34a and 34b can be formed in an appropriate thickness which can facilitate removal of the thermal stress.

Now, the effects of the invention will be explained in detail with reference to specific examples.

### EXAMPLE 1

In Example 1, a dielectric layer made of BiZnNb-based oxide in a thickness of 200 nm was formed on a substrate at room temperature via RF sputtering. A target having a composition of Bi_{1.5}Zn_{1.0}Nb_{1.5} was used for the sputtering. The sputtering was conducted at 3×10⁻⁶ Torr, in an oxygen atmosphere containing 10% of Ar, and the distance from the target to the substrate was set about 10 cm.

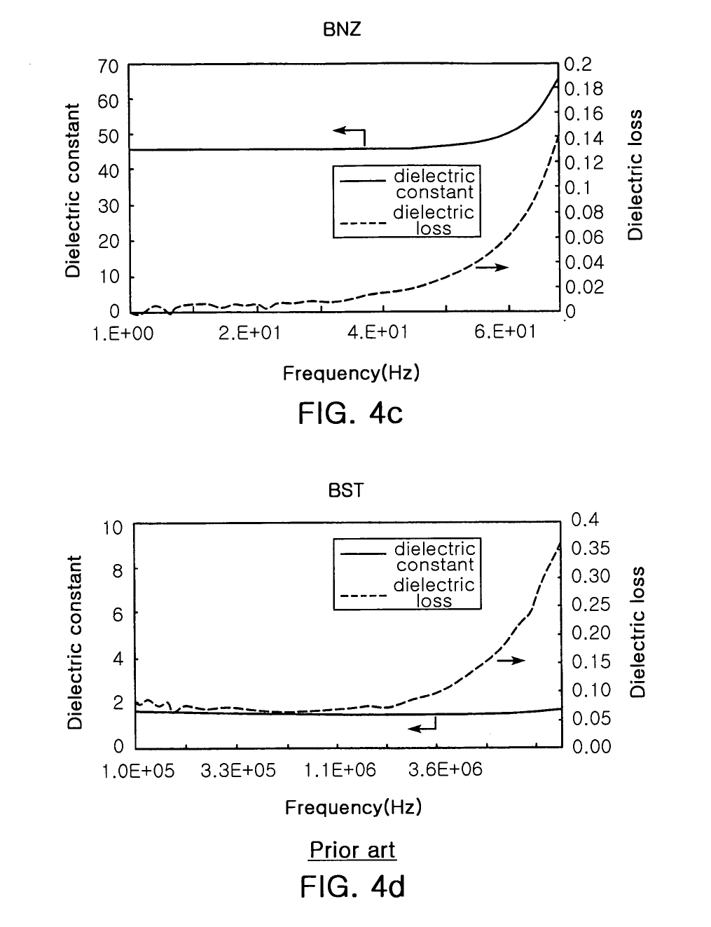

The resultant BiZnNb-based dielectric layer was not thermally treated, and the dielectric constants and dielectric losses were measured in the high frequency range. The measurement results are shown in FIG. 4a.

### EXAMPLE 2

In Example 2, a BiZnNb-based dielectric material was formed on a substrate in a thickness of 200 nm at room temperature via RF sputtering, similar to Example 1, except that a different composition of the sputtering target was used so that a different composition range of the dielectric layer was adopted for Example 2. That is, the sputtering was conducted at 3×10⁻⁶ Torr in an oxygen atmosphere containing 10% of Ar, and the distance from the target to the substrate was set about 10 cm, except that the composition of the target used was Bi_{1.59}Zn_{1.0}Nb_{1.5} in this Example.

The resultant BiZnNb-based dielectric layer was not thermally treated, and the dielectric constants and dielectric losses were measured in the high frequency range. The measurement results are shown in the graph in FIG. 4b.

### EXAMPLE 3

In Example 3, a dielectric layer of BiZnNb-based oxide is formed on a substrate in a thickness of 200 nm at room temperature via PLD. The composition of the target used was Bi_{1.5}Zn_{1.0}Nb_{1.5}, same as in Example 1. The PLD was conducted at 50 mTorr in an oxygen atmosphere containing 10% of Ar, and the distance from the target to the substrate was set about 10 cm.

The resultant BiZnNb-based dielectric layer was thermally treated at a low temperature of 120° C., and the dielectric constants and the dielectric losses were measured in the high frequency range. The measurement results are shown in the graph in FIG. 4c.

### COMPARATIVE EXAMPLE

In this experiment, a dielectric layer of BaSrTi-based oxide was formed on a substrate in a thickness of 200 nm at room temperature via RF sputtering. The composition of the sputtering target used was Ba_{1.0}Sr_{1.5}Ti_{1.2} in this experiment. The sputtering was conducted at 3×10⁻⁶ Torr in an oxygen atmosphere containing 10% of Ar, and the distance from the target to the substrate was set about 10 cm.

The resultant BST-based dielectric layer was not thermally treated, and the dielectric constants and the dielectric losses were measured in the high frequency region. The measurement results are shown in the graph in FIG. 4d.

With reference to FIGS. 4a to 4c, the dielectric layers obtained from Examples 1 to 3 according to the present invention showed high dielectric constants and low dielectric losses. The dielectric layers obtained from Examples 1 to 3 exhibited the dielectric constants of 15, 30, and 47, respectively, in the high frequency range (of several MHz), and exhibited low dielectric losses overall. On the contrary, the dielectric layer, in which BaTi-based oxide known as high dielectric material was not thermally treated, showed a low dielectric constant of below 2, and exhibited relatively large losses.

Therefore, unlike the conventional high dielectric material which requires thermal treatment to obtain a high dielectric constant, it was confirmed that the BiZnNb-based metal oxide adopted in this invention has a high level of dielectric constant, in an amorphous state after low-temperature deposition, and the level of dielectric constant is practicable for a thin layer capacitor.

In addition, when the dielectric layer is expressed as BiₓZn_{y}Nb_{z}O₇, it was confirmed that the preferable ranges are 1.3<x<2.0, 0.8<y<1.5, and 1.4<z<1.6, considering the composition range of the target used in Examples 1 to 3 and formation process of the amorphous oxide.

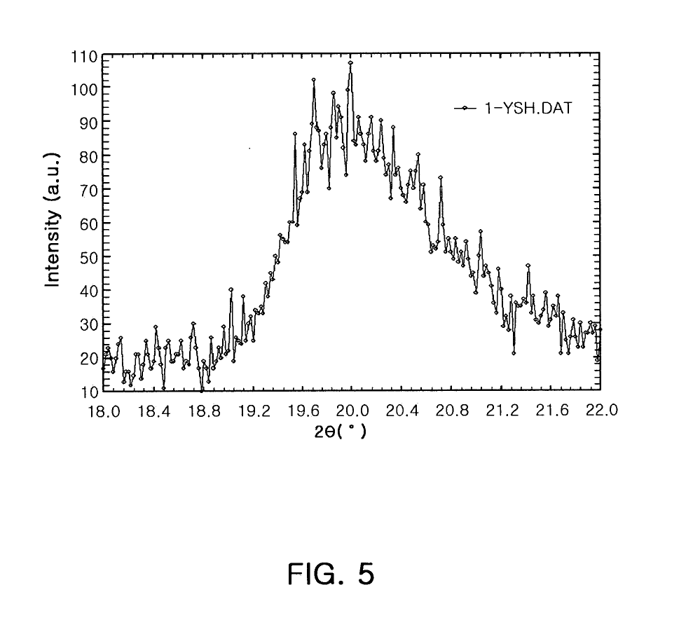

FIG. 5 is a graph showing the results of the XRD analysis of the (Bi, Zn, Ni)-based dielectric layer obtained from Example 1.

As confirmed in FIG. 5, the BiZnNi-based dielectric layer obtained from Example 1 has an intensity of up to 100 in vicinity of 20°, in which the intensity profile is distributed in 2θ range of 4°. The results of the XRD analysis indicate that the BiZnNi-based dielectric layer obtained from this example is in an amorphous state having no crystallinity like pyrochlore phase.

The present invention set forth above provides BiZnNi-based metal oxide having a high dielectric constant of at least 15, preferably at least 30, and most preferably at least 45, without a high temperature thermal treatment for crystallization. As described so far, the dielectric layer of BiZnNi-based amorphous metal oxide does not require high-temperature process, and therefore, can be applied positively to a thin layer capacitor or polymer-based composite layered structure for a PCB.

While the present invention has been shown and described in connection with the preferred embodiments, it will be apparent to those skilled in the art that modifications and variations can be made without departing from the spirit and scope of the invention as defined by the appended claims.

1. A thin layer capacitor comprising first and second metal electrode layers and a dielectric layer of BiZnNb-based amorphous metal oxide interposed between the metal layers, the dielectric layer having a dielectric constant of at least 15.

2. The thin layer capacitor according to claim 1, wherein the BiZnNb-based amorphous metal oxide is expressed as BiₓZn_{y}Nb_{z}O₇, where 1.3<x<2.0, 0.8<y<1.5, and 1.4<z<1.6.

3. The thin layer capacitor according to claim 1, wherein the dielectric layer has a dielectric constant of at least 30.

4. The thin layer capacitor according to claim 1, wherein the dielectric layer has a thickness of 50 nm to 1 μm.

5. The thin layer capacitor according to claim 1, wherein at least one of the first and second metal electrode layers is made of at least one selected from a group consisting of Cu, Ni, Al, Pt, Ta, and Ag.

6. The thin layer capacitor according to claim 1, further comprising a buffer layer between at least one of the first and second metal electrode layers and the dielectric layer to enhance adhesion between the at least one metal electrode layer and the dielectric layer.

7. The thin layer capacitor according to claim 6, wherein the buffer layer is made of Ni.

8. A layered structure comprising:
a first metal electrode layer formed on a polymer-based composite substrate;
a dielectric layer, formed on the first metal electrode layer, the dielectric layer made of BiZnNb-based metal oxide with a dielectric constant of at least 15; and
a second metal electrode layer formed on the dielectric layer.

9. The layered structure according to claim 8, wherein the BiZnNb-based metal oxide is expressed as BiₓZn_{y}Nb_{z}O₇, where 1.3<x<2.0, 0.8<y<1.5, and 1.4<z<1.6.

10. The layered structure according to claim 8, wherein the dielectric layer has a dielectric constant of at least 30.

11. The layered structure according to claim 8, wherein the dielectric layer has a thickness of about 50 nm to 1 μm.

12. The layered structure according to claim 8, wherein at least one of the first and second metal electrode layers is made of at least one selected from a group consisting of Cu, Ni, Al, Pt, Ta, and Ag.

13. The layered structure according to claim 8, further comprising a buffer layer between at least one of the first and second metal electrode layer and the dielectric layer to enhance adhesion between the at least one of the first and second metal electrode layer and the dielectric layer.

14. The layered structure according to claim 8, wherein the buffer layer is made of Ni.

15. The layered structure according to claim 8, wherein the polymer-based composite substrate comprises polyimide or epoxy.

16. The layered structure according to claim 8, comprising a Printed Circuit Board (PCB).

17. A fabrication method of a thin layer capacitor comprising steps of:
forming a dielectric layer on a first metal electrode layer, the dielectric layer made of a BiZnNb-based metal oxide with a dielectric constant of at least 15; and forming a second electrode layer on the dielectric layer.

18. The fabrication method of a thin layer capacitor according to claim 17, wherein the step of forming a dielectric layer is conducted using low-temperature deposition at a temperature up to 100° C.

19. The fabrication method of a thin layer capacitor according to claim 18, wherein the step of forming a dielectric layer comprises one selected from a group consisting of low-temperature sputtering, Pulsed Laser Deposition and Chemical Vapor Deposition.

20. The fabrication method of a thin layer capacitor according to claim 18, further comprising a step of thermal treatment at a temperature range in which the metal composite is not crystallized, after the step of forming a dielectric layer.

21. The fabrication method of a thin layer capacitor according to claim 20, wherein the thermal treatment of the dielectric layer is conducted at a temperature ranging from 100 to 200° C.

22. The fabrication method of a thin layer capacitor according to claim 17, wherein the BiZnNb-based metal oxide is expressed as BiₓZn_{y}Nb_{z}O₇, where 1.3<x<2.0, 0.8<y<1.5, and 1.4<z<1.6.

23. The fabrication method of a thin layer capacitor according to claim 17, wherein the dielectric layer has a dielectric constant of at least 30.

24. The fabrication method of a thin layer capacitor according to claim 17, wherein the dielectric layer has a thickness of 50 nm to 1 μm.

25. The fabrication method of a thin-layer capacitor according to claim 17, wherein the step of forming a second metal electrode layer comprises one selected from a group consisting of sputtering conductible at low temperature, evaporation, and electroless plating.

26. The fabrication method of a thin layer capacitor according to claim 17, wherein at least one of the first and second metal electrode layers is made of at least one selected from a group consisting of Cu, Ni, Al, Pt, Ta, and Ag.

27. The fabrication method of a thin layer capacitor according to claim 17, further comprising a step of forming a buffer layer between the first metal electrode layer and the dielectric layer to enhance adhesion between the first metal electrode layer and the dielectric layer, before the step of forming the dielectric layer.

28. The fabrication method of a thin layer capacitor according to claim 17, further comprising a step of forming a buffer layer between the second metal electrode layer and the dielectric layer to enhance adhesion between the second metal electrode layer and the dielectric layer, between the step of forming the dielectric layer and the step of forming the second metal electrode layer.

29. The fabrication method of a thin layer capacitor according to claim 28, wherein the buffer layer is made of Ni.

30. A fabrication method of a layered structure comprising steps of:
forming a first metal electrode layer on a polymer-based composite substrate;
forming a dielectric layer on the first metal electrode layer, the dielectric layer made of a BiZnNb-based metal oxide with a dielectric constant of at least 15; and
forming a second metal electrode layer on the dielectric layer.

31. The fabrication method of a layered structure according to claim 30, wherein the step of forming a dielectric layer is conducted using low-temperature deposition at a temperature up to 100° C.

32. The fabrication method of a layered structure according to claim 31, wherein the step of forming a dielectric layer comprises one selected from a group consisting of low-temperature sputtering, PLD and CVD.

33. The fabrication method of a layered structure according to claim 30, further comprising a step of thermal treatment conducted on a condition that the metal composite is not crystallized and the substrate is not deformed, after the step of forming a dielectric layer.

34. The fabrication method of a layered structure according to claim 33, wherein the thermal treatment of the dielectric layer is conducted at a temperature ranging from 100 to 200° C.

35. The fabrication method of a layered structure according to claim 30, wherein the BiZnNb-based metal oxide is expressed as BiₓZn_{y}Nb_{z}O₇, where 1.3<x<2.0, 0.8<y<1.5, and 1.4<z<1.6.

36. The fabrication method of a layered structure according to claim 30, wherein the dielectric layer has a dielectric constant of at least 30.

37. The fabrication method of a layered structure according to claim 30, wherein the dielectric layer has a thickness of 50 nm to 1 μm.

38. The fabrication method of a layered structure according to claim 30, wherein the step of forming first and second metal electrode layers comprises one selected from a group consisting of low-temperature sputtering, evaporation, and electroless plating.

39. The fabrication method of a layered structure according to claim 30, wherein at least one of the first and second metal electrode layers is made of at least one selected from a group consisting of Cu, Ni, Al, Pt, Ta, and Ag.

40. The fabrication method of a layered structure according to claim 30, further comprising a step of forming a buffer layer between the first metal electrode layer and the dielectric layer to enhance adhesion between the first metal electrode layer and the dielectric layer, before the step of forming the dielectric layer.

41. The fabrication method of a layered structure according to claim 30, further comprising a buffer layer between the second metal electrode layer and the dielectric layer to enhance adhesion between the second metal electrode layer and the dielectric layer, between the step of forming the dielectric layer and the step of forming the dielectric layer.

42. The fabrication method of a layered structure according to claim 40, wherein the buffer layer is made of Ni.

43. The fabrication method of a layered structure according to claim 30, wherein the polymer-based composite substrate comprises polyimide or epoxy.

44. The fabrication method of a layered structure according to claim 30, wherein the layered structure comprises a Printed Circuit Board (PCB).

45. The fabrication method of a layered structure according to claim 30, further comprising a step of compressing the polymer-based composite substrate on the second metal electrode layer.

46. The fabrication method of a layered structure according to claim 31, further comprising a step of thermal treatment conducted on a condition that the metal composite is not crystallized and the substrate is not deformed, after the step of forming a dielectric layer.

47. The fabrication method of a layered structure according to claim 41, wherein the buffer layer is made of Ni.
